(19) United States
(12) Patent Application Publication
(10) Pub. No.: US 2026/0024734 A1
(43) Pub. Date: Jan. 22, 2026

(54) SUBSTRATE SUPPORT STAGE AND SUBSTRATE PROCESSING APPARATUS

(71) Applicant: Tokyo Electron Limited, Tokyo (JP)

(72) Inventor: Shingo KOIWA, Miyagi (JP)

(21) Appl. No.: 19/340,007

(22) Filed: Sep. 25, 2025

Related U.S. Application Data
(63) Continuation of application No. PCT/JP2024/011475, filed on Mar. 22, 2024.

(30) Foreign Application Priority Data
Apr. 5, 2023 (JP) 2023-061597

(51) Int. Cl. H01J 37/32

(52) U.S. Cl. CPC H01J 37/32715; H01J 37/32091; H01J 37/32697

(57) ABSTRACT

A substrate support stage and a substrate processing apparatus that improve the cooling performance of a substrate is provided. A substrate support stage includes a base having a lower surface, a first upper surface having a circular shape and located opposite the lower surface, and a second upper surface having an annular shape, located opposite the lower surface and closer to the lower surface than the first upper surface is, and surrounding a periphery of the first upper surface; a first electrostatic chuck disposed over the first upper surface and including a first ceramic member and a first electrostatic electrode disposed in the first ceramic member; and a second electrostatic chuck formed separately from the first electrostatic chuck, disposed over the second upper surface, and including a second ceramic member and a second electrostatic electrode disposed in the second ceramic member.

### CROSS-REFERENCE TO RELATED APPLICATION

This application is a continuation of International Application No. PCT/JP2024/011475, filed on Mar. 22, 2024 and designating the U.S., which claims priority to Japanese Patent Application No. 2023-061597, filed on Apr. 5, 2023. The contents of these applications are incorporated herein by reference in their entirety.

### TECHNICAL FIELD

The present disclosure relates to a substrate support stage and a substrate processing apparatus.

### BACKGROUND ART

Japanese Unexamined Patent Application Publication No. 2020-205379 describes a stage including an electrostatic chuck that supports a substrate and an edge ring, and a base that supports the electrostatic chuck. The electrostatic chuck includes a first region having a first upper surface and supports the substrate placed on the first upper surface; a second region having a second upper surface, provided integrally around the first region, and supports the edge ring placed on the second upper surface; a first electrode provided in the first region and configured to apply a DC voltage; a second electrode provided in the second region and configured to apply a DC voltage, and a third electrode configured to apply a bias power.

### SUMMARY

According to one embodiment of the present disclosure, there is provided a substrate support stage including: a base having a lower surface, a first upper surface having a circular shape and located opposite the lower surface, and a second upper surface having an annular shape, located opposite the lower surface, formed closer to the lower surface than the first upper surface is, and surrounding a periphery of the first upper surface; a first electrostatic chuck disposed over the first upper surface and including a first ceramic member and a first electrostatic electrode disposed in the first ceramic member; and a second electrostatic chuck formed separately from the first electrostatic chuck, disposed over the second upper surface, and including a second ceramic member and a second electrostatic electrode disposed in the second ceramic member.

### BRIEF DESCRIPTION OF THE DRAWINGS

FIG. 1 is an example of a diagram illustrating an example configuration of a capacitively coupled plasma processing apparatus;

FIG. 2 is an example of a diagram illustrating a configuration of a substrate support according to a first embodiment;

FIG. 3 is an example of a partially enlarged cross-sectional view of a base;

FIG. 4 is an example of a diagram illustrating a configuration of a substrate support according to a second embodiment;

FIG. 5 is an example of a diagram illustrating a configuration of a substrate support according to a third embodiment;

FIG. 6 is an example of a diagram illustrating a configuration of a substrate support according to a fourth embodiment;

FIG. 7A is an example of a diagram illustrating a configuration of the substrate support according to the fourth embodiment;

FIG. 7B is an example of a diagram illustrating a configuration of the substrate support according to the fourth embodiment;

FIG. 7C is an example of a diagram illustrating a configuration of the substrate support according to the fourth embodiment;

FIG. 7D is an example of a diagram illustrating a configuration of the substrate support according to the fourth embodiment;

FIG. 7E is an example of a diagram illustrating a configuration of the substrate support according to the fourth embodiment;

FIG. 7F is an example of a diagram illustrating a configuration of the substrate support according to the fourth embodiment;

FIG. 8 is an example of a diagram illustrating a configuration of a substrate support according to a fifth embodiment;

FIG. 9 is an example of a diagram illustrating a configuration of a substrate support according to a sixth embodiment;

FIG. 10 is an example of a diagram illustrating a configuration of a substrate support according to a seventh embodiment;

FIG. 11 is an example of a diagram illustrating a configuration of a substrate support according to an eighth embodiment; and

FIG. 12 is an example of a diagram illustrating a configuration of a substrate support according to a ninth embodiment.

### DETAILED DESCRIPTION

Various exemplary embodiments will be described in detail below with reference to the drawings. Note that, in the drawings, the same or corresponding parts are denoted by the same reference numerals.

### [Plasma Processing System]

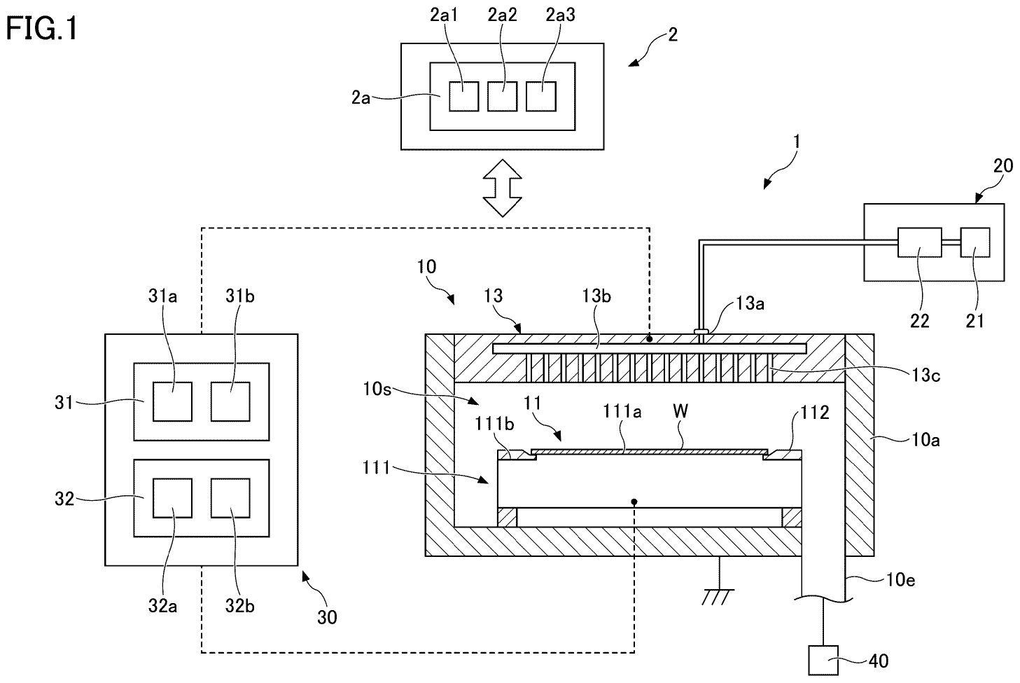

An example of a configuration of a plasma processing system will be described below. FIG. 1 is an example of a diagram illustrating an example configuration of a capacitively coupled plasma processing apparatus (substrate processing apparatus) 1.

The plasma processing system includes the capacitively coupled plasma processing apparatus 1 and a controller 2. The capacitively coupled plasma processing apparatus 1 includes a plasma processing chamber 10, a gas supply 20, a power supply 30, and an exhaust system 40. Further, the plasma processing apparatus 1 includes a substrate support 11 and a gas introduction section. The gas introduction section is configured to introduce at least one processing gas into the plasma processing chamber 10. The gas introduction section includes a showerhead 13. The substrate support 11 is disposed in the plasma processing chamber 10. The showerhead 13 is disposed above the substrate support 11. In one embodiment, the showerhead 13 constitutes at least a portion of a ceiling of the plasma processing chamber 10. The plasma processing chamber 10 includes a plasma processing space 10s defined by the showerhead 13, a side wall 10a of the plasma processing chamber 10, and the substrate support 11. The plasma processing chamber 10 includes at least one gas supply port for supplying at least one processing gas to the plasma processing space 10s, and at least one gas discharge port for discharging the gas from the plasma processing space 10s. The plasma processing chamber 10 is grounded. The showerhead 13 and the substrate support 11 are electrically isolated from a housing of the plasma processing chamber 10.

The substrate support 11 includes a body (substrate support stage) 111 and a ring assembly 112. The body 111 includes a central region 111a for supporting a substrate W and an annular region 111b for supporting the ring assembly 112. A wafer is an example of the substrate W. The annular region 111b of the body 111 surrounds the central region 111a of the body 111 in a plan view. The substrate W is disposed on the central region 111a of the body 111, and the ring assembly 112 is disposed on the annular region 111b of the body 111 so as to surround the substrate W on the central region 111a of the body 111. Thus, the central region 111a is also referred to as a substrate support surface for supporting the substrate W, and the annular region 111b is also referred to as a ring support surface for supporting the ring assembly 112.

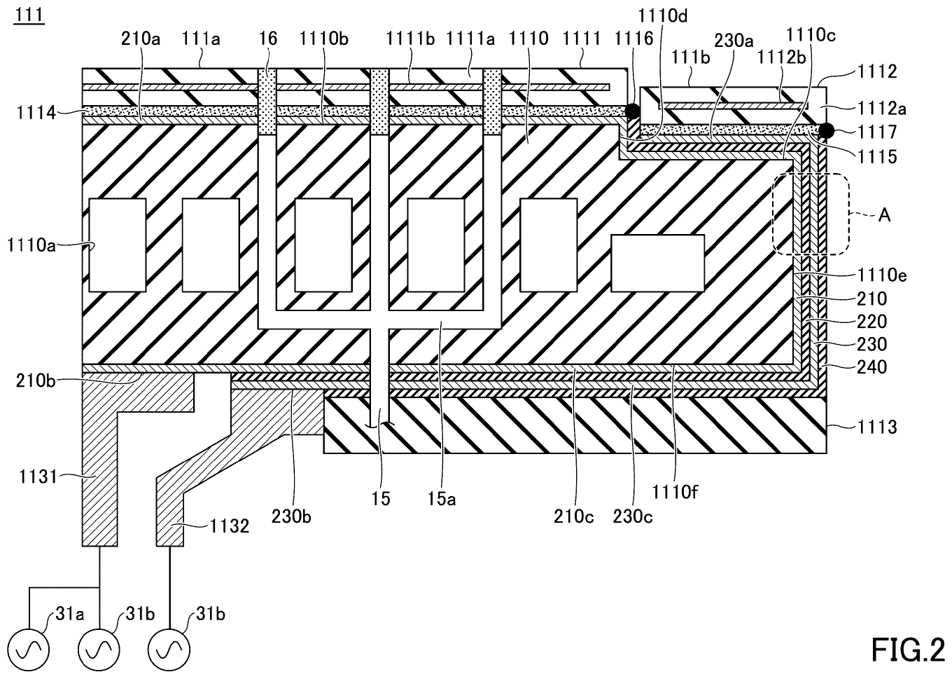

In one embodiment, the body 111 includes a base 1110, a first electrostatic chuck 1111, and a second electrostatic chuck 1112 as illustrated in FIG. 2 described later. The base 1110 includes a conductive member. The conductive member of the base 1110 can function as a lower electrode. The first electrostatic chuck 1111 is disposed over the base 1110. The first electrostatic chuck 1111 includes a ceramic member 1111a and an electrostatic electrode 1111b disposed in the ceramic member 1111a. The ceramic member 1111a includes the central region 111a. The second electrostatic chuck 1112 is disposed over the base 1110. Further, the second electrostatic chuck 1112 is formed in an annular shape and is disposed to surround the first electrostatic chuck 1111 in a plan view from above. The second electrostatic chuck 1112 includes a ceramic member 1112a and an electrostatic electrode 1112b disposed in the ceramic member 1112a. The ceramic member 1112a includes the annular region 111b. Note that another member surrounding the second electrostatic chuck 1112, such as an annular insulating member, may include the annular region 111b. In this case, the ring assembly 112 may be disposed on the annular insulating member, or may be disposed on both the second electrostatic chuck 1112 and the annular insulating member. In addition, at least one RF/DC electrode coupled to a radio frequency (RF) power supply 31 and/or a direct current (DC) power supply 32, which will be described later, may be disposed in the ceramic member 1111a. In this case, at least one RF/DC electrode functions as a lower electrode. In a case where a bias RF signal and/or a DC signal, which will be described later, are supplied to at least one RF/DC electrode, the RF/DC electrode is also be referred to as a bias electrode. Note that the conductive member of the base 1110 and at least one RF/DC electrode may function as a plurality of lower electrodes. Further, the electrostatic electrode 1111b may function as a lower electrode. Accordingly, the substrate support 11 includes at least one lower electrode.

The ring assembly 112 includes one or more annular members. In one embodiment, the one or more annular members include one or more edge rings and at least one cover ring. The edge rings are formed of a conductive material or an insulating material, and the cover ring is formed of an insulating material.

Further, the substrate support 11 may include a temperature adjustment module configured to adjust at least one of the first electrostatic chuck 1111, the second electrostatic chuck 1112, the ring assembly 112, or the substrate W to a target temperature. The temperature adjustment module may include a heater, a heat transfer medium, a flow channel 1110a, or a combination thereof. A heat transfer fluid, such as brine or gas, flows through the flow channel 1110a. In one embodiment, the flow channel 1110a is formed in the base 1110, and one or more heaters are disposed in the ceramic member 1111a of the first electrostatic chuck 1111 and/or the ceramic member 1112a of the second electrostatic chuck 1112. Further, the substrate support 11 may include a heat transfer gas supply configured to supply a heat transfer gas to a gap between a back surface of the substrate W and the central region 111a.

The showerhead 13 is configured to introduce at least one processing gas from the gas supply 20 into the plasma processing space 10s. The showerhead 13 includes at least one gas supply port 13a, at least one gas diffusion chamber 13b, and a plurality of gas introduction ports 13c. The processing gas supplied to the gas supply port 13a is introduced into the plasma processing space 10s from the plurality of gas introduction ports 13c through the gas diffusion chamber 13b. Further, the showerhead 13 includes at least one upper electrode. Note that the gas introduction section may include, in addition to the showerhead 13, one or more side gas injectors (SGIs) attached to one or more openings formed in the side wall 10a.

The gas supply 20 may include at least one gas source 21 and at least one flow controller 22. In one embodiment, the gas supply 20 is configured to supply at least one processing gas from the corresponding gas source 21 to the showerhead 13 via the corresponding flow controller 22. Each flow controller 22 may include, for example, a mass flow controller or a pressure-controlled flow controller. Further, the gas supply 20 may include one or more flow modulation devices configured to modulate or pulse the flow of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. With this configuration, plasma is formed from at least one processing gas supplied into the plasma processing space 10s. Thus, the RF power supply 31 can function as at least a part of a plasma generator configured to generate plasma from one or more processing gases in the plasma processing chamber 10. Further, by supplying the bias RF signal to at least one lower electrode, a bias potential is generated in the substrate W, and ion components in the formed plasma can be drawn into the substrate W.

In one embodiment, the RF power supply 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is coupled to at least one lower electrode via at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal or the bias RF signal may be pulsed.

Further, in a case where the body 111 of the substrate support 11 includes a plurality of lower electrodes and the same bias RF signal or different bias RF signals are supplied to the electrodes, the RF power supply 31 may include a plurality of second RF generators 31b, and the bias RF signal or signals may be supplied to the lower electrodes from the respective independent second RF generators 31b.

Further, the power supply 30 may include the DC power supply 32 coupled to the plasma processing chamber 10. The DC power supply 32 includes a first DC generator 32a and a second DC generator 32b. In one embodiment, the first DC generator 32a is connected to at least one lower electrode and is configured to generate a first DC signal. The generated first DC signal is applied to at least one lower electrode. In one embodiment, the second DC generator 32b is connected to at least one upper electrode and is configured to generate a second DC signal. The generated second DC signal is applied to at least one upper electrode.

In various embodiments, at least one of the first DC signal or the second DC signal may be pulsed. In this case, a sequence of voltage pulses is applied to at least one lower electrode and/or at least one upper electrode. The voltage pulses may have a rectangular waveform, a trapezoidal waveform, a triangular waveform, or a combination of these pulse waveforms. In one embodiment, a waveform generator for generating a sequence of voltage pulses from a DC signal is connected between the first DC generator 32a and at least one lower electrode. Thus, the first DC generator 32a and the waveform generator constitute a voltage pulse generator. When the second DC generator 32b and the waveform generator constitute the voltage pulse generator, the voltage pulse generator is connected to at least one upper electrode. The voltage pulses may have positive polarity or negative polarity. Additionally, the sequence of voltage pulses may include one or more positive polarity voltage pulses and one or more negative polarity voltage pulses in one cycle. Note that the first and second DC generators 32a and 32b may be provided in addition to the RF power supply 31, or the first DC generator 32a may be provided instead of the second RF generator 31b.

The exhaust system 40 can be connected to a gas discharge port 10e provided at the bottom of the plasma processing chamber 10, for example. The exhaust system 40 may include a pressure regulating valve and a vacuum pump. The pressure regulating valve regulates the pressure in the plasma processing space 10s. The vacuum pump may include a turbomolecular pump, a dry pump, or a combination thereof.

The controller 2 processes computer-executable instructions that cause the plasma processing apparatus 1 to perform various processes described in the present disclosure. The controller 2 may be configured to control components of the plasma processing apparatus 1 to perform the various processes described herein. In one embodiment, a part of or the entirety of the controller 2 may be included in the plasma processing apparatus 1. The controller 2 may include a processing unit 2a1, a storage unit 2a2, and a communication interface 2a3. The controller 2 may be implemented by, for example, a computer 2a. The processing unit 2al may be configured to read a program from the storage unit 2a2 and execute the read program to perform various control operations. The program may be stored in the storage unit 2a2 in advance or may be acquired via a medium when necessary. The acquired program is stored in the storage unit 2a2 and is read from the storage unit 2a2 and executed by the processing unit 2a1. The medium may be any of various storage media readable by the computer 2a, or may be a communication line connected to the communication interface 2a3. The processing unit 2al may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

### [Substrate Support]

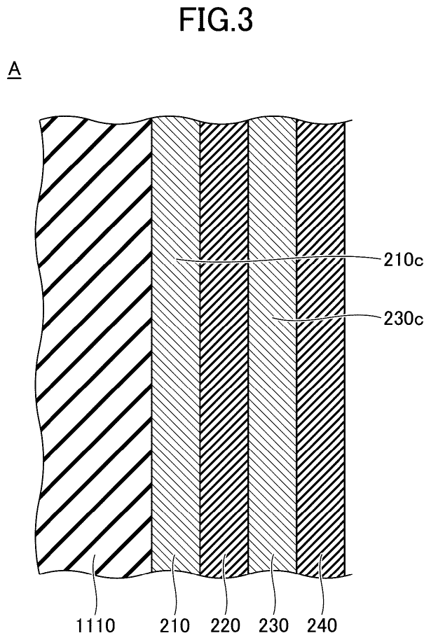

Next, a configuration of a body 111 of a substrate support 11 according to a first embodiment will be described with reference to FIG. 2 and FIG. 3. FIG. 2 is an example of a schematic cross-sectional view illustrating the configuration of the body 111 of the substrate support 11 according to the first embodiment. FIG. 3 is an example of a partially enlarged cross-sectional view of an outer peripheral portion (a range indicated by a dashed line in FIG. 2) of a base 1110. In addition, FIG. 2 is a schematic cross-sectional view of the substrate support 11 taken at a position at which a heat transfer gas flow channel 15, a porous member 16, and the like are arranged. Therefore, in FIG. 2, a conductive layer 210 is illustrated as being divided by the heat transfer gas flow channel 15, the porous member 16, and the like; however, in reality, portions of the conductive layer 210 are also located in regions other than where the heat transfer gas flow channel 15, the porous member 16, and the like are arranged, and are electrically connected to each other. The same applies to a conductive layer 230. The same applies to other drawings described later.

The body 111 includes the base 1110, a first electrostatic chuck 1111, a second electrostatic chuck 1112, and a support member 1113.

The base 1110 is formed of an insulating material. Specifically, the base 1110 is formed of an insulating material having lower thermal expansion than Al. Specifically, an insulating material having a coefficient of thermal expansion (CTE) in the range of 4 ppm/° C. to 10 ppm/° C. can be used. Specifically, for example, SiC, AlN, or Al₂O₃ can be used. A flow channel 1110a through which a heat transfer fluid flows is formed in the base 1110. The base 1110 has a lower surface 1110f, a first upper surface 1110b, and a second upper surface 1110c. The first upper surface 1110b and the second upper surface are located opposite the lower surface 1110f. The first upper surface 1110b is formed in a circular shape and is formed at a position higher than the second upper surface 1110c. That is, the first upper surface 1110b is formed at a position farther from the lower surface 1110f than the second upper surface 1110c is. The second upper surface 1110c is formed in an annular shape surrounding the first upper surface 1110b in a plan view, and is formed at a position lower than the first upper surface 1110b. That is, the second upper surface 1110c is formed at a position closer to the lower surface 1110f than the first upper surface 1110b is. The first electrostatic chuck 1111 is disposed over and fixed to the first upper surface 1110b via an adhesive layer 1114. The second electrostatic chuck 1112 is disposed over and fixed to the second upper surface 1110c via an adhesive layer 1115. The adhesive layers 1114 and 1115 may be formed of a material having a thermal conductivity of 1 W/mK or more. In addition, the thickness of the adhesive layers 1114 and 1115 may be 200 μm or less.

Further, the base 1110 has a first side surface 1110d and a second side surface 1110e. The first side surface 1110d is a side surface formed in a cylindrical shape between an outer peripheral end of the first upper surface 1110b and an inner peripheral end of the second upper surface 1110c. The second side surface 1110e is a side surface formed in a cylindrical shape between an outer peripheral end of the second upper surface 1110c and an outer peripheral end of the lower surface 1110f. The lower surface 1110f is a surface formed in a circular shape.

The conductive layer 210 (a first conductive layer), an insulating layer 220 (a first insulating layer), the conductive layer 230 (a second conductive layer), and an insulating layer 240 (a second insulating layer) are formed and stacked on surfaces of the base 1110.

The conductive layer 210 is formed on surfaces of the base 1110 including at least the first upper surface 1110b. The conductive layer 210 is formed of, for example, Al. The conductive layer 210 is formed across the first upper surface 1110b, the first side surface 1110d, the second upper surface 1110c, the second side surface 1110e, and the lower surface 1110f. The conductive layer 210 includes a conductive layer 210a, a conductive layer 210b, and a conductive layer 210c. The conductive layer 210a is a portion of the conductive layer 210 that is formed on the first upper surface 1110b and is not covered by the insulating layer 220. The conductive layer 210b is a portion of the conductive layer 210 that is formed on the lower surface 1110f and is not covered by the insulating layer 220. The conductive layer 210c is a portion of the conductive layer 210 that electrically connects the conductive layer 210a and the conductive layer 210b, is formed across the first side surface 1110d, the second upper surface 1110c, the second side surface 1110e, and the lower surface 1110f, and is covered by the insulating layer 220. The conductive layer 210a, which is a portion of the conductive layer 210 formed on the first upper surface 1110b, is supplied with an RF signal for plasma generation and functions as a lower terminal. Further, the conductive layer 210a is supplied with a first bias RF signal and functions as a substrate-side bias electrode. That is, the conductive layer 210a is supplied with at least one of the RF signal for plasma generation or the first bias signal. Further, the conductive layers 210b and 210c, which are portions of the conductive layer 210 formed on the lower surface 1110f, the second side surface 1110e, the second upper surface 1110c, and the first side surface 1110d, function as interconnect layers to the conductive layer 210a functioning as the lower electrode and/or the substrate-side bias electrode. The thickness of the conductive layer 210 can be in the range of 50 μm to 500 μm, for example.

The insulating layer 220 is formed so as to cover at least a portion of the conductive layer 210. The insulating layer 220 electrically insulates the conductive layer 210 and the conductive layer 230 from each other. The insulating layer 220 is formed of, for example, Al₂O₃, Y₂O₃, AlN, PI, or the like. The insulating layer 220 is located on the outer side of the conductive layer 210 and formed across the lower surface 1110f, the second side surface 1110e, the second upper surface 1110c, and the first side surface 1110d. That is, the insulating layer 220 is formed so as to cover the conductive layer 210c, the conductive layer 210b is exposed at a portion of the lower surface 1110f, and the conductive layer 210a is exposed at the first upper surface 1110b. Note that the conductive layer 210a formed on the first upper surface 1110b is covered by the adhesive layer 1114 and the first electrostatic chuck 1111. Note that the insulating layer 220 may be formed so as to cover the conductive layer 210 on the first upper surface 1110b. Note that the insulating layer 220 may be formed by thermal spraying or coating. The thickness of the insulating layer 220 is, for example, in the range of 50 μm to 1,000 μm, and in a case where the insulating layer 220 is formed to be thinner, the insulating layer 220 may have a thickness in the range of 50 μm to 600 μm.

The conductive layer 230 is formed over surfaces of the base 1110 including at least the second upper surface 1110c. The conductive layer 230 is, for example, an Al layer. The conductive layer 230 is located on the outer side of the insulating layer 220 and formed across the lower surface 1110f, the second side surface 1110e, and the second upper surface 1110c. The conductive layer 230 includes a conductive layer 230a, a conductive layer 230b, and a conductive layer 230c. The conductive layer 230a is a portion of the conductive layer 230 that is formed on the second upper surface 1110c and not covered by the insulating layer 240. The conductive layer 230b is a portion of the conductive layer 230 that is formed on the lower surface 1110f and not covered by the insulating layer 240. The conductive layer 230c is a portion of the conductive layer 230 that electrically connects the conductive layer 230a and the conductive layer 230b, is formed across the second side surface 1110e and the lower surface 1110f, and is covered by the insulating layer 240. The conductive layer 230a, which is a portion of the conductive layer 230 formed on the second upper surface 1110c, is supplied with a second bias RF signal and functions as an edge-ring-side bias electrode. Further, the conductive layers 230b and 230c, which are portions of the conductive layer 230 formed on the lower surface 1110f and the second side surface 1110e, function as interconnect layers to the conductive layer 230a functioning as the edge-ring-side bias electrode. The thickness of the conductive layer 230 can be in the range of 50 μm to 500 μm, for example.

The insulating layer 240 is formed so as to cover at least a portion of the conductive layer 230. The insulating layer 240 is provided such that the conductive layer 230 is not exposed to the plasma processing space 10s. The insulating layer 240 is formed of, for example, Al₂O₃, Y₂O₃, AlN, PI, or the like. The insulating layer 240 is located on the outer side of the conductive layer 230 and formed across the lower surface 1110f and the second side surface 1110e. That is, the insulating layer 240 is formed so as to cover the conductive layer 230c, the conductive layer 230b is exposed at a portion of the lower surface 1110f, and the conductive layer 230a is exposed at the second upper surface 1110c. Note that the conductive layer 230a formed over the second upper surface 1110c is covered by the adhesive layer 1115 and the second electrostatic chuck 1112. Note that the insulating layer 240 may be formed so as to cover the conductive layer 230 over the second upper surface 1110c. Note that the insulating layer 240 may be formed by thermal spraying or coating. The thickness of the insulating layer 240 is, for example, in the range of 50 μm to 1,000 μm, and in a case where the insulating layer 240 is formed to be thinner, the insulating layer 240 may have a thickness in the range of 50 μm to 600 μm.

The first electrostatic chuck 1111 includes a central region 111a for supporting a substrate W. The first electrostatic chuck 1111 is disposed over the first upper surface 1110b of the base 1110 via the adhesive layer 1114. The outer peripheral side of the adhesive layer 1114 is sealed by a seal member 1116 (for example, an O-ring). With this configuration, consumption of the adhesive layer 1114 by a processing gas, plasma, or the like can be suppressed. The first electrostatic chuck 1111 includes a ceramic member 1111a (a first ceramic member) and an electrostatic electrode 1111b (a first electrostatic electrode) disposed in the ceramic member 1111a. Further, the thickness of the ceramic member 1111a is 2 mm or less, and in a case where the ceramic member 1111a is formed to be thinner, the ceramic member 1111a may have a thickness in the range of 0.3 mm to 1 mm.

The second electrostatic chuck 1112 is formed separately from the first electrostatic chuck 1111. The second electrostatic chuck 1112 includes an annular region 111b for supporting a ring assembly 112 (for example, an edge ring). The second electrostatic chuck 1112 is disposed over the second upper surface 1110c of the base 1110 via the adhesive layer 1115. The inner peripheral side of the adhesive layer 1115 is sealed by the seal member 1116. The outer peripheral side of the adhesive layer 1115 is sealed by a seal member 1117 (for example, an O-ring). With this configuration, consumption of the adhesive layer 1115 by a processing gas, plasma, or the like can be suppressed. The second electrostatic chuck 1112 includes a ceramic member 1112a (a second ceramic member) and an electrostatic electrode 1112b (a second electrostatic electrode) disposed in the ceramic member 1112a. Further, the thickness of the ceramic member 1112a is 2 mm or less, and in a case where the ceramic member 1112a is formed to be thinner, the ceramic member 1112a may have a thickness in the range of 0.3 mm to 1 mm.

The support member 1113 is formed of, for example, an insulating material, and is disposed under the base 1110. The support member 1113 is fixed to a back surface of the base 1110 by, for example, a fastening member (not illustrated) such as a bolt.

An electrical connection member 1131 is formed of a conductive material and is electrically connected to the conductive layer 210b at the lower surface 1110f of the base 1110. The source RF signal for plasma generation is supplied to the electrical connection member 1131 from the first RF generator 31a. Further, the first bias RF signal is supplied to the electrical connection member 1131 from the second RF generator 31b.

An electrical connection member 1132 is formed of a conductive material and is electrically connected to the conductive layer 230b at the lower surface 1110f of the base 1110. The second bias RF signal is supplied to the electrical connection member 1132 from the second RF generator 31b.

Note that the RF power supply 31 may include a plurality of independent second RF generators 31b, and one second RF generator 31b may supply the first bias RF signal to the electrical connection member 1131, and another second RF generator 31b may supply the second bias RF signal to the electrical connection member 1132.

The power supply 30 supplies the source RF signal for plasma generation and the first bias RF signal from the electrical connection member 1131 to the conductive layer 210a functioning as the lower electrode and the bias electrode.

A contact point between the electrical connection member 1131 and the conductive layer 210 is formed on the lower surface 1110f side of the base 1110. Therefore, the contact area between the electrical connection member 1131 and the conductive layer 210 can be increased. This can reduce heat generation at the contact point between the electrical connection member 1131 and the conductive layer 210. Further, by forming the contact point, serving as a heat generator, between the electrical connection member 1131 and the conductive layer 210 on the lower surface 1110f side of the base 1110, it is possible to reduce a temperature rise of the substrate W supported by the substrate support 11.

The source RF signal and the first bias RF signal supplied from the lower surface 1110f of the base 1110 pass through the portions of the conductive layer 210 serving as the interconnect layers formed on the outer peripheral surface of the base 1110, and reach the conductive layer 210a. Therefore, the cross-sectional area of the interconnect layers through which a current passes can be increased. This can reduce heat generation of the conductive layer 210.

Similarly, heat generation at a contact point between the electrical connection member 1132 and the conductive layer 230 can be reduced. In addition, heat generation of the conductive layer 230 can be reduced.

Further, an electrostatic chuck is divided into the first electrostatic chuck 1111 and the second electrostatic chuck 1112, and the first electrostatic chuck 1111 and the second electrostatic chuck 1112 are formed separately from each other. Further, the first upper surface 1110b is formed so as to be higher than the second upper surface 1110c. Accordingly, the thickness of the ceramic member 1111a of the first electrostatic chuck 1111 can be reduced as compared to when electrostatic chucks are integrally formed.

Further, by forming the conductive layer 210a, functioning as the lower electrode and the bias electrode, on the surface of the base 1110, the thickness of the ceramic member 1111a of the first electrostatic chuck 1111 can be reduced. Accordingly, the thermal conductivity between the substrate W and the base 1110 can be improved, and the substrate W can be cooled suitably.

Further, by reducing the thickness of the ceramic member 1111a, a difference in temperature between the upper surface and the lower surface of the ceramic member 1111a can be reduced. This can also reduce a thermal expansion difference due to the difference in temperature between the upper surface and the lower surface of the ceramic member 1111a. Therefore, warpage of the ceramic member 1111a can be reduced.

Further, by reducing the thickness of the ceramic member 1111a, the distance between the substrate W and the conductive layer 210a functioning as the lower electrode and the bias electrode can be reduced. Therefore, abnormal discharge in the heat transfer gas flow channel 15 formed in the ceramic member 1111a can be suppressed.

Similarly, the thickness of the ceramic member 1112a of the second electrostatic chuck 1112 can be reduced. Therefore, warpage of the ceramic member 1112a can be reduced.

Further, a distribution flow channel 15a of the heat transfer gas flow channel 15 is formed in the base 1110. That is, a flow channel of the heat transfer gas flow channel 15 formed in the first electrostatic chuck 1111 extends in the thickness direction (vertical direction) of the first electrostatic chuck 1111, and a flow channel extending in a direction (horizontal direction) along the surface of the first electrostatic chuck 1111 need not be provided. Accordingly, the thickness of the ceramic member 1111a can be reduced as compared to a configuration in which a distribution flow channel of the heat transfer gas flow channel 15 is formed in the first electrostatic chuck 1111.

The configuration of the substrate support 11 is not limited to the configuration illustrated in FIG. 2 and FIG. 3.

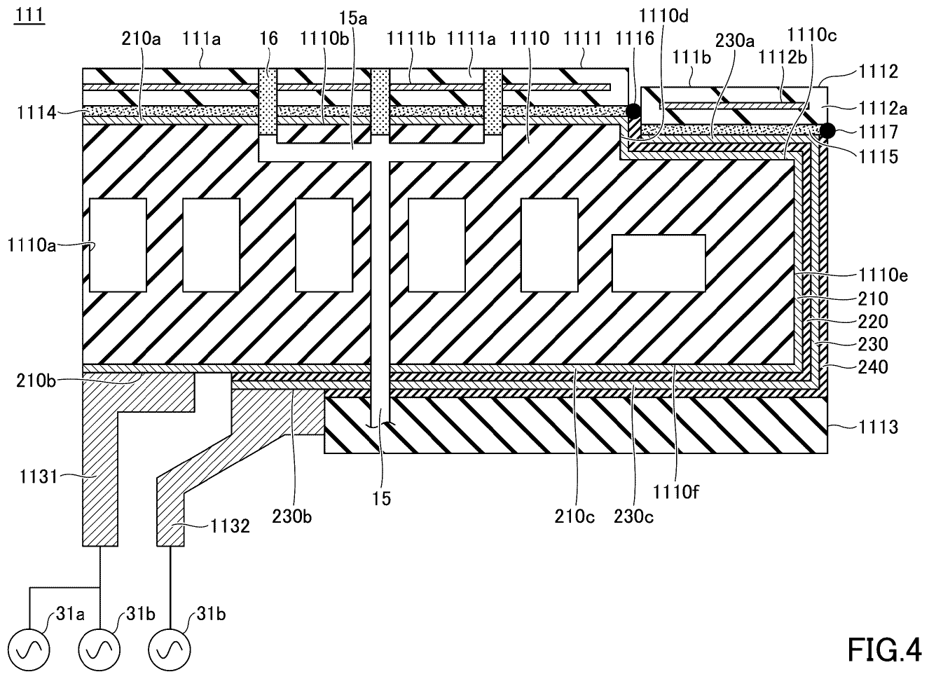

FIG. 4 is an example of a diagram illustrating a configuration of a substrate support 11 according to a second embodiment. Similar to the example illustrated in FIG. 2 described above, a lower electrode and a substrate-side bias electrode is formed as a conductive layer 210a on the base 1110, and an edge-ring-side bias electrode is formed as a conductive layer 230a over the base 1110.

Further, in the example illustrated in FIG. 2, the distribution flow channel 15a of the heat transfer gas flow channel 15 is formed in the base 1110 between the flow channel 1110a and the lower surface 1110f. The position at which the distribution flow channel 15a is formed is not limited thereto. As illustrated in FIG. 4, the distribution flow channel 15a of the heat transfer gas flow channel 15 may be formed in the base 1110 between the flow channel 1110a and the upper surface (first upper surface 1110b). The other configurations are the same as those described above, and a duplicate description will be omitted.

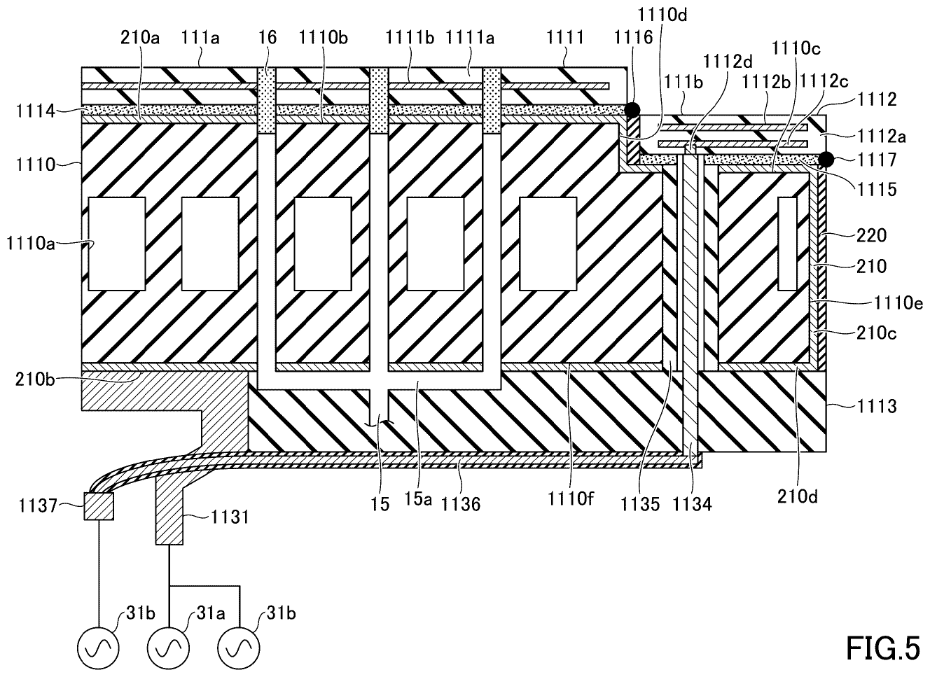

FIG. 5 is an example of a diagram illustrating a configuration of a substrate support 11 according to a third embodiment. Similar to the example illustrated in FIG. 2, a lower electrode and a substrate-side bias electrode are formed as a conductive layer 210a on the base 1110. Note that, in FIG. 5, a cross-sectional view of the substrate support 11 taken at a position at which an interconnect 1112d, a power feed rod 1134, and the like are arranged. Therefore, a conductive layer 210 illustrated in FIG. 5 is illustrated as being divided into the inner peripheral side and the outer peripheral side by the interconnect 1112d, the power feed rod 1134, and the like; however, in reality, portions of the conductive layer 210 are also located in regions other than where the interconnect 1112d, the power feed rod 1134, and the like are arranged, and are electrically connected to each other.

The conductive layer 210 includes the conductive layer 210a, a conductive layer 210b, a conductive layer 210c, and a conductive layer 210d. Herein, an insulating layer 220 is formed so as to cover at least a portion of the conductive layer 210. Further, the insulating layer 220 is provided such that the conductive layer 210 is not exposed to the plasma processing space 10s. The conductive layer 210a is a portion of the conductive layer 210 that is formed on a first upper surface 1110b and is not covered by the insulating layer 220. The conductive layer 210b is a portion of the conductive layer 210 that is formed on a lower surface 1110f and is not covered by the insulating layer 220 and the support member 1113. The conductive layer 210c is a portion of the conductive layer 210 that is formed across a first side surface 1110d, a second upper surface 1110c, and a second side surface 1110e and is covered by the insulating layer 220. The conductive layer 210d is a portion of the conductive layer 210 that is formed on the lower surface 1110f and is covered by the support member 1113. The conductive layer 210c and the conductive layer 210d electrically connect the conductive layer 210a and the conductive layer 210b.

As illustrated in FIG. 5, the lower electrode and the substrate-side bias electrode are formed as the conductive layer 210a on the base 1110. An edge-ring-side bias electrode is formed as a bias electrode 1112c in a second electrostatic chuck 1112. The interconnect 1112d formed of a conductive material is formed on the back surface side of the second electrostatic chuck 1112 so as to connect the back surface of the second electrostatic chuck 1112 to the bias electrode 1112c. The interconnect 1112d is, for example, a via. The base 1110 is provided with the power feed rod 1134 and a sleeve 1135. The upper end of the power feed rod 1134 is connected to the interconnect 1112d. The lower end of the power feed rod 1134 is connected to an electrical connection member 1137 via a power feed line 1136. A second bias RF signal is supplied to the electrical connection member 1137 from the second RF generator 31b. The other configurations are the same as those described above, and a duplicate description will be omitted.

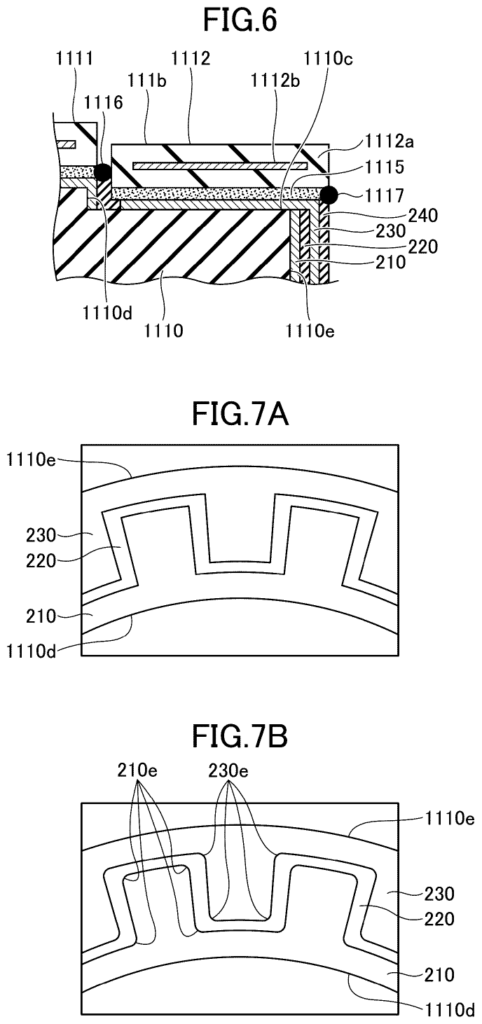

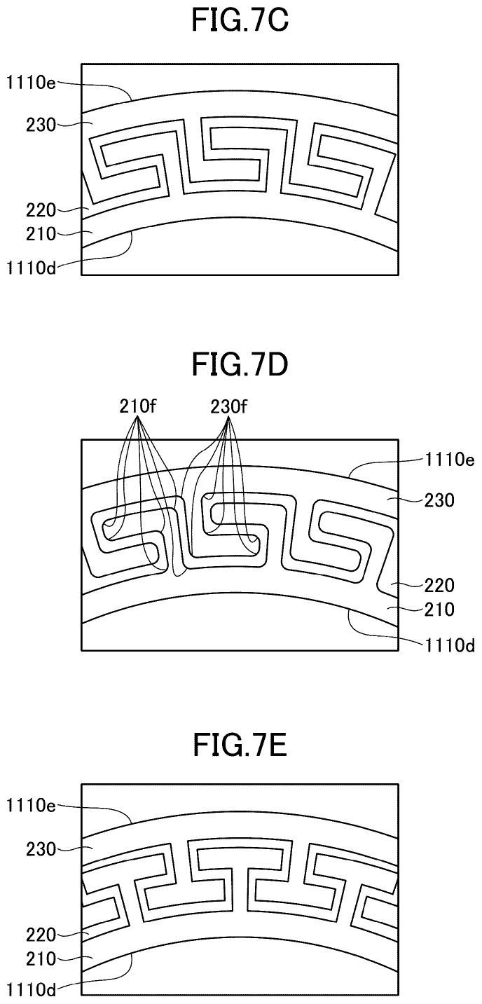

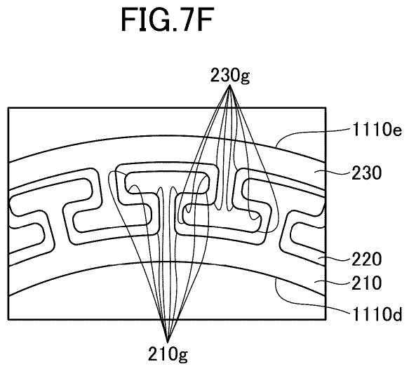

FIG. 6 is an example of a diagram illustrating a configuration of a substrate support 11 according to a fourth embodiment. FIG. 7A to FIG. 7F are diagrams illustrating examples of the arrangement of conductive layers 210 and 230 on a second upper surface 1110c of a base 1110 of the substrate support 11 according to the fourth embodiment. In other words, FIG. 7A to FIG. 7F are diagrams illustrating examples of the arrangement of the conductive layer 210, an insulating layer 220, and the conductive layer 230 when the second upper surface 1110c is viewed from above.

In the example illustrated in FIG. 2, three layers, which are the conductive layer 210, the insulating layer 220, and the conductive layer 230, are sequentially stacked on the second upper surface 1110c of the base 1110 in the thickness direction. In contrast, in the substrate support 11 illustrated in FIG. 6, the conductive layer 210, the insulating layer 220, and the conductive layer 230 are arranged on a plane on the second upper surface 1110c. That is, the conductive layer 210, the insulating layer 220, and the conductive layer 230 may be formed as a single layer on the second upper surface 1110c in the thickness direction. The other configurations are the same as those described above, and a duplicate description will be omitted.

For example, as illustrated in FIG. 7A, the conductive layer 210, the insulating layer 220, and the conductive layer 230 may be formed in one layer by being alternately arranged in the circumferential direction. As illustrated in FIG. 7B, corner portions 210e and 230e of the conductive layer 210 and the conductive layer 230 may be rounded. In this case, electric field concentrations at the corner portions are suppressed.

For example, as illustrated in FIG. 7C, the conductive layer 210, the insulating layer 220, and the conductive layer 230 may be formed in one layer by being alternately arranged in a nested structure in the circumferential direction. As illustrated in FIG. 7D, corner portions 210f and 230f of the conductive layer 210 and the conductive layer 230 may be rounded. In this case, electric field concentrations at the corner portions are suppressed.

For example, as illustrated in FIG. 7E, the conductive layer 210, the insulating layer 220, and the conductive layer 230 may be formed in one layer by being alternately arranged in a nested structure in the circumferential direction. As illustrated in FIG. 7F, corner portions 210g and 230g of the conductive layer 210 and the conductive layer 230 may be rounded. In this case, electric field concentrations at the corner portions are suppressed.

Accordingly, the thermal conductivity between a second electrostatic chuck 1112 and the base 1110 can be improved.

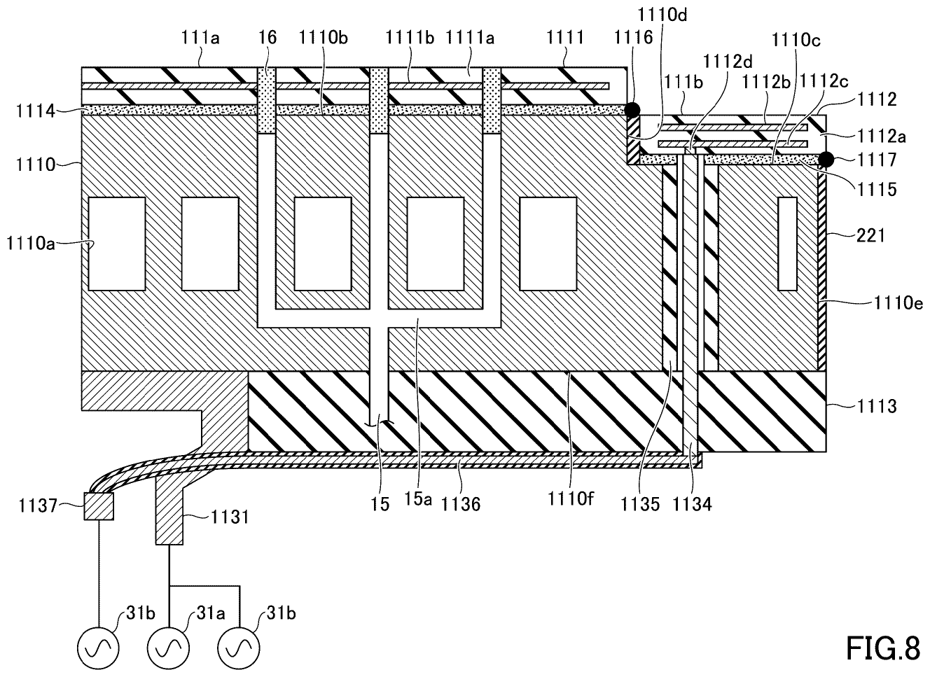

FIG. 8 is an example of a diagram illustrating a configuration of a substrate support 11 according to a fifth embodiment.

In the substrate support 11 according to the fifth embodiment, a base 1110 is formed of a conductive material, specifically, a material containing molybdenum (Mo) (an Mo alloy). Herein, ceramic members 1111a and 1112a are formed of, for example, Al₂O₃. By using a material containing molybdenum (Mo) as a material of the base 1110, a thermal expansion difference between the base and Al₂O₃ can be reduced as compared to SiC. This can reduce distortion of adhesive layers 1114 and 1115. In addition, the base 1110 formed of a metal material can suppress the occurrence of cracks. The base 1110 may be formed of a material containing tungsten (W) (a W alloy). Alternatively, the base 1110 may be formed of a material containing silicon-aluminum (Si—Al) (an Si—Al alloy).

Further, the base 1110 functions as a lower electrode and a substrate-side bias electrode. Further, similar to the example illustrated in FIG. 5, a bias electrode 1112c functioning as an edge-ring-side bias electrode is formed in a second electrostatic chuck 1112.

Further, an insulating layer 221 is formed on the surface of the base 1110. The insulating layer 221 is formed so as to cover at least a portion of the base 1110. Further, the insulating layer 221 is provided such that the base 1110 is not exposed to the plasma processing space 10s. The insulating layer 221 is formed of, for example, Al₂O₃, Y₂O₃, AlN, PI, or the like. Note that the insulating layer 221 may be formed by thermal spraying or coating. The thickness of the insulating layer 221 is, for example, in the range of 50 μm to 1,000 μm, and in a case where the insulating layer 221 is formed so as to be thinner, the insulating layer 221 may have a thickness in the range of 50 μm to 600 μm.

The other configurations are the same as those described above, and a duplicate description will be omitted.

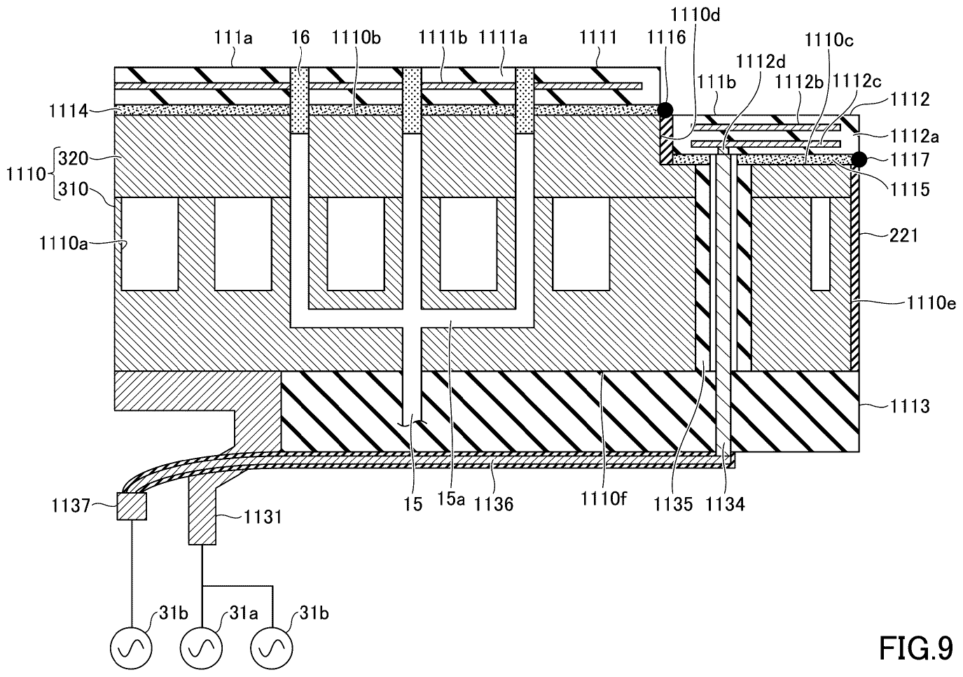

FIG. 9 is an example of a diagram illustrating a configuration of a substrate support 11 according to a sixth embodiment.

Similar to the example illustrated in FIG. 8, in the substrate support 11 according to the sixth embodiment, a base 1110 functions as a lower electrode and a substrate-side bias electrode. Further, similar to the example illustrated in FIG. 8, a bias electrode 1112c functioning as an edge-ring-side bias electrode is formed in a second electrostatic chuck 1112.

Herein, the base 1110 is formed by bonding together a first base 310 and a second base 320. The first base 310 and the second base 320 are formed of different conductive materials. The second base 320 can be formed of a metal material having a coefficient of thermal expansion (CTE) in the range of 4 ppm/° C. to 7 ppm/° C., for example. Specifically, the second base 320 is formed of a material containing molybdenum (Mo), tungsten (W), Si—Al, or the like (an Mo alloy, a W alloy, an Si—Al alloy, or the like). The first base 310 can be formed of a nonmagnetic metal. Specifically, the first base 310 is formed of a material containing aluminum (Al) or formed of stainless steel (SUS: steel use stainless as referred to in the Japanese Industrial Standards).

The first base 310 and the second base 320 can be bonded together by friction stir welding, aluminum brazing, or the like.

A recess that is to serve as a flow channel 1110a is formed in the upper surface of the first base 310. The flow channel 1110a is formed by bonding the first base 310, in which the recess is formed, and the second base 320 together. The flow channel 1110a can be easily formed in the base 1110 by forming the recess, which is to serve as the flow channel 1110a, in the first base 310 that is formed of a material having good processability. The other configurations are the same as those described above, and a duplicate description will be omitted.

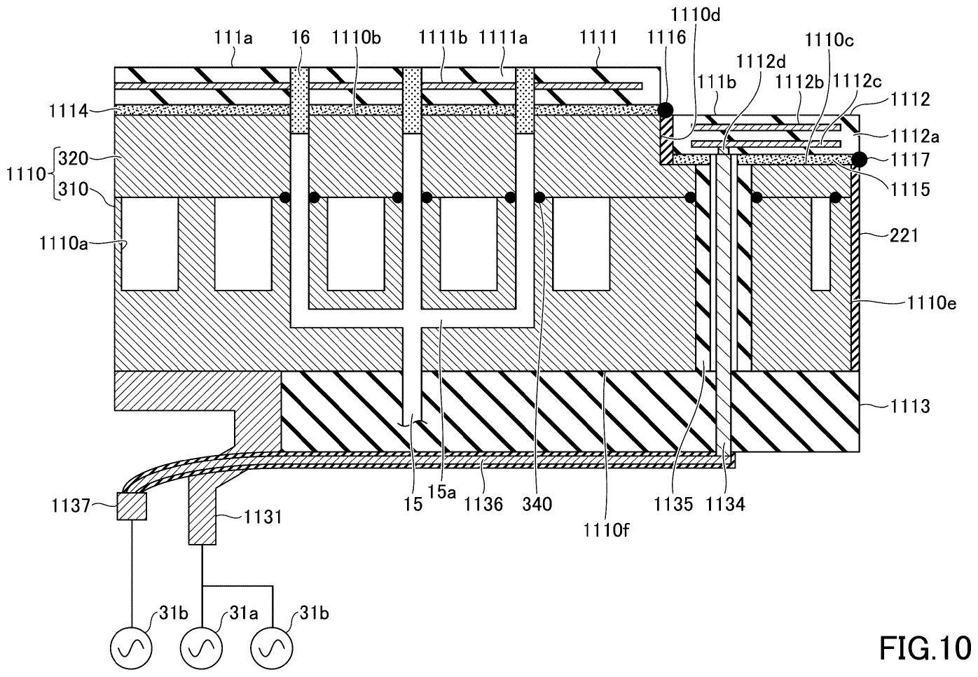

FIG. 10 is an example of a diagram illustrating a configuration of a substrate support 11 according to a seventh embodiment.

Similar to the example illustrated in FIG. 8, in the substrate support 11 according to the seventh embodiment, a base 1110 functions as a lower electrode and a substrate-side bias electrode. Further, similar to the example illustrated in FIG. 8, a bias electrode 1112c functioning as an edge-ring-side bias electrode is formed in a second electrostatic chuck 1112.

In the substrate support 11 according to the seventh embodiment, the base 1110 is formed by fixing a first base 310 and a second base 320 with a fastening member (not illustrated) such as a bolt. Further, a seal member 340 such as an O-ring for sealing a heat transfer gas flow channel 15 and a flow channel 1110a, which is a heat transfer medium, is provided between the first base 310 and the second base 320. The other configurations are the same as those described above, and a duplicate description will be omitted.

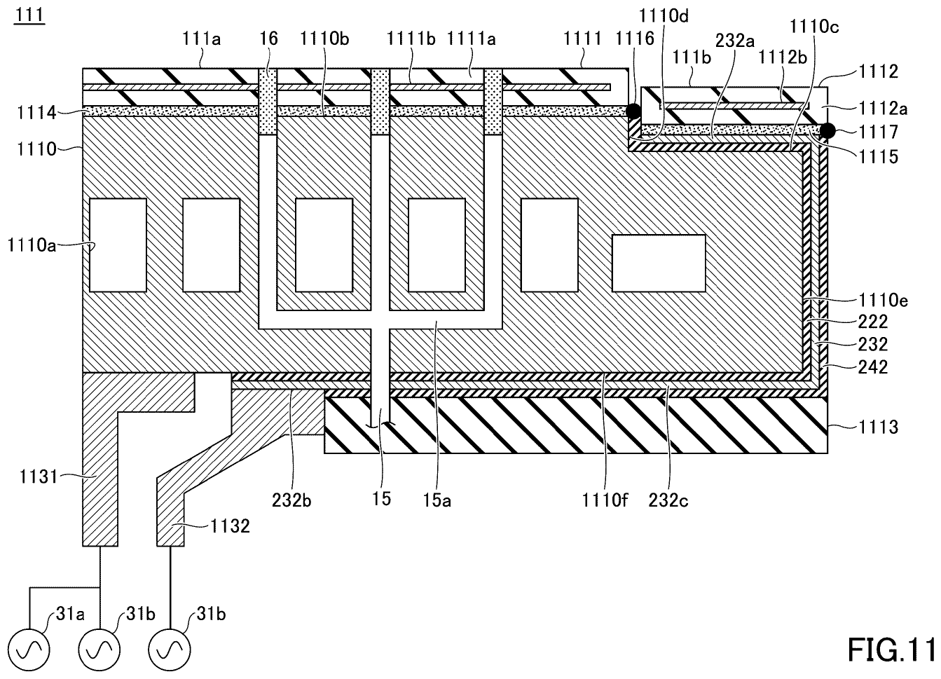

FIG. 11 is an example of a diagram illustrating a configuration of a substrate support 11 according to an eighth embodiment.

Similar to the example illustrated in FIG. 8, in the substrate support 11 according to the eighth embodiment, a base 1110 functions as a lower electrode and a substrate-side bias electrode. Further, an insulating layer 222 (a first insulating layer), a conductive layer 232, and an insulating layer 242 (a second insulating layer) are formed and stacked on surfaces of the base 1110. An edge-ring-side bias electrode is formed as a conductive layer 232a over the base 1110.

The insulating layer 222 is formed so as to cover at least a portion of the base 1110. The insulating layer 222 electrically insulates the base 1110 and the conductive layer 232 from each other. The insulating layer 222 is formed of, for example, Al₂O₃, Y₂O₃, AlN, PI, or the like. The insulating layer 222 is formed on surfaces of the base 1110 including at least a second upper surface 1110c. Specifically, the insulating layer 222 is formed across a lower surface 1110f, a second side surface 1110e, the second upper surface 1110c, and a first side surface 1110d. Further, the insulating layer 222 electrically insulates the base 1110 and the conductive layer 232 from each other. The insulating layer 222 may be formed by thermal spraying or coating. The thickness of the insulating layer 222 is, for example, in the range of 50 μm to 1,000 μm, and in a case where the insulating layer 222 is formed so as to be thinner, the insulating layer 222 may have a thickness in the range of 50 μm to 600 μm.

The conductive layer 232 is formed on the insulating layer 222 at least on the second upper surface 1110c. The conductive layer 232 is, for example, an Al layer. Specifically, the insulating layer 222 is formed across the lower surface 1110f, the second side surface 1110e, and the second upper surface 1110c. The conductive layer 232 includes the conductive layer 232a, a conductive layer 232b, and a conductive layer 232c. The conductive layer 232a is a portion of the conductive layer 232 that is formed over the second upper surface 1110c and is not covered by the insulating layer 242. The conductive layer 232b is a portion of the conductive layer 232 that is formed over the lower surface 1110f and is not covered by the insulating layer 242. The conductive layer 232c is a portion of the conductive layer 232 that electrically connects the conductive layer 232a and the conductive layer 232b, is formed across the second side surface 1110e and the lower surface 1110f, and is covered by the insulating layer 242. The conductive layer 232a, which is a portion of the conductive layer 232 formed on the second upper surface 1110c, is supplied with a second bias RF signal and functions as an edge-ring-side bias electrode. Further, a portion of the conductive layer 232 formed on the lower surface 1110f and the second side surface 1110e function as an interconnect layer to the conductive layer 232a functioning as the edge-ring-side bias electrode. The thickness of the conductive layer 232 is in the range of 50 μm to 500 μm.

The insulating layer 242 is formed so as to cover at least a portion of the conductive layer 232. The insulating layer 242 is provided such that the conductive layer 232 is not exposed to the plasma processing space 10s. The insulating layer 242 is formed of, for example, Al₂O₃, Y₂O₃, AlN, PI, or the like. Note that the insulating layer 242 may be formed by thermal spraying or coating. The thickness of the insulating layer 242 is, for example, in the range of 50 μm to 1,000 μm, and in a case where the insulating layer 242 is formed so as to be thinner, the insulating layer 242 may have a thickness in the range of 50 μm to 600 μm.

The other configurations are the same as those described above, and a duplicate description will be omitted.

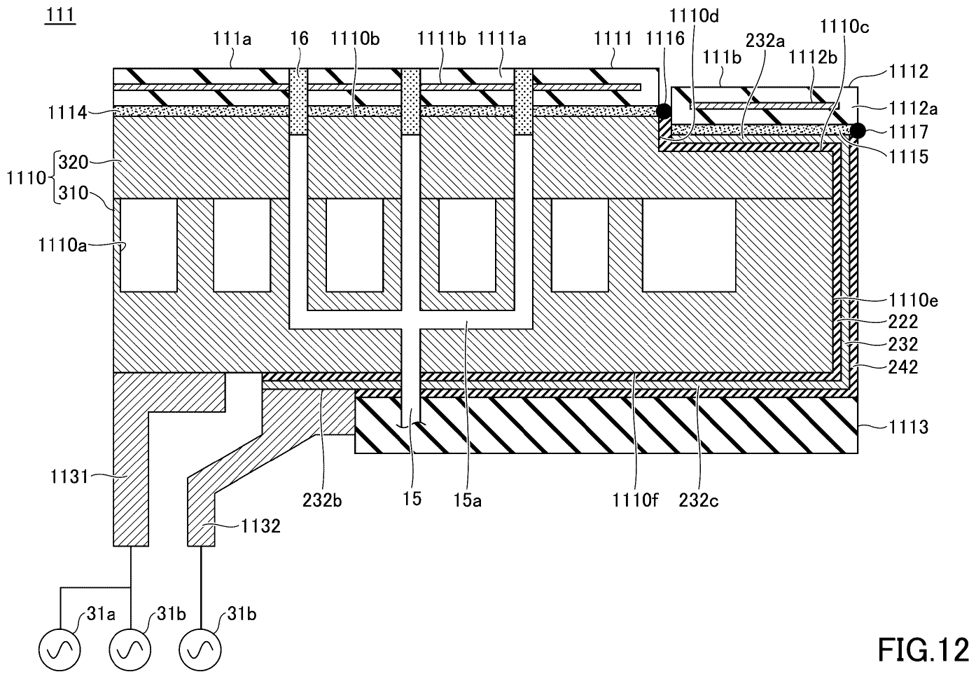

FIG. 12 is an example of a diagram illustrating a configuration of a substrate support 11 according to a ninth embodiment.

Similar to the example illustrated in FIG. 9, in the substrate support 11 according to the eighth embodiment, a base 1110 functions as a lower electrode and a substrate-side bias electrode. Further, the base 1110 is formed by bonding together a first base 310 and a second base 320. In the base 1110, the first base 310 and the second base 320 may be fixed to each other by a fastening member (not illustrated) such as a bolt. The other configurations are the same as those described above, and a duplicate description will be omitted.

The above-described embodiments include, for example, the following aspects.

### (Clause 1)

A substrate support stage including:
a base having a lower surface, a first upper surface having a circular shape and located opposite the lower surface, and a second upper surface having an annular shape, located opposite the lower surface and closer to the lower surface than the first upper surface is, and surrounding a periphery of the first upper surface;
a first electrostatic chuck disposed over the first upper surface and including a first ceramic member and a first electrostatic electrode disposed in the first ceramic member; and
a second electrostatic chuck formed separately from the first electrostatic chuck, disposed over the second upper surface, and including a second ceramic member and a second electrostatic electrode disposed in the second ceramic member.

### (Clause 2)

The substrate support stage according to clause 1, further including:
a first conductive layer formed on surfaces of the base and supplied with at least one of a radio frequency (RF) signal for plasma generation or a first bias signal, the surfaces including at least the first upper surface; and
a first insulating layer covering at least a portion of the first conductive layer, wherein
the base is formed of an insulating material.

### (Clause 3)

The substrate support stage according to clause 2, wherein the first conductive layer is formed across the first upper surface, a first side surface between the first upper surface and the second upper surface, the second upper surface, a second side surface between the second upper surface and the lower surface, and the lower surface.

### (Clause 4)

The substrate support stage according to clause 3, further including:
a second conductive layer formed on surfaces of the base and supplied with a second bias signal, the surfaces including at least the second upper surface; and
a second insulating layer covering at least a portion of the second conductive layer.

### (Clause 5)

The substrate support stage according to clause 4, wherein the second conductive layer is formed across the second upper surface, the second side surface, and the lower surface.

### (Clause 6)

The substrate support stage according to clause 2 or 3, wherein the second electrostatic chuck includes a bias electrode disposed in the second ceramic member and is supplied with a second bias signal.

### (Clause 7)

The substrate support stage according to clause 1, wherein
the base is formed of a conductive material, and,
the base is supplied with at least one of an RF signal for plasma generation or a first bias signal.

### (Clause 8)

The substrate support stage according to clause 7, wherein the base includes a first base including the lower surface of the base, and a second base including the first upper surface and the second upper surface and formed of a material different from a material of the first base.

### (Clause 9)

The substrate support stage according to clause 8, wherein the first base and the second base are bonded to each other.

### (Clause 10)

The substrate support stage according to clause 8, wherein the first base and the second base are fixed to each other by a fastening member.

### (Clause 11)

The substrate support stage according to any one of clauses 8 to 10, wherein
the first base is formed of aluminum (Al) or stainless steel, and
the second base is formed of a molybdenum (Mo) alloy, a tungsten (W) alloy, or a silicon-aluminum (Si—Al) alloy.

### (Clause 12)

The substrate support stage according to any one of clauses 7 to 11, further including:
a first insulating layer formed on surfaces of the base including at least the second upper surface;
a second conductive layer formed on the first insulating layer at least on the second upper surface and supplied with a second bias signal; and
a second insulating layer covering at least a portion of the second conductive layer.

### (Clause 13)

The substrate support stage according to any one of clauses 7 to 11, wherein
the second electrostatic chuck includes a bias electrode disposed in the second ceramic member and is supplied with a second bias signal.

### (Clause 14)

The substrate support stage according to any one of clauses 1 to 13, wherein a thickness of the first electrostatic chuck is 1 mm or less.

### (Clause 15)

A substrate processing apparatus including:
the substrate support stage of any one of clauses 1 to 14.

It should be noted that the present invention is not limited to the configurations described in the above embodiments, and may be combined with other elements and the like. These points can be changed without departing from the spirit of the present invention, and can be appropriately determined according to the application form.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

According to one embodiment of the present disclosure, a substrate support stage and a substrate processing apparatus that improve the cooling performance of a substrate can be provided.

What is claimed is:

1. A substrate support stage comprising:
a base having a lower surface, a first upper surface having a circular shape and located opposite the lower surface, and a second upper surface having an annular shape, located opposite the lower surface and closer to the lower surface than the first upper surface is, and surrounding a periphery of the first upper surface;
a first electrostatic chuck disposed over the first upper surface and including a first ceramic member and a first electrostatic electrode disposed in the first ceramic member; and
a second electrostatic chuck formed separately from the first electrostatic chuck, disposed over the second upper surface, and including a second ceramic member and a second electrostatic electrode disposed in the second ceramic member.

2. The substrate support stage according to claim 1, further comprising:
a first conductive layer formed on surfaces of the base and supplied with at least one of a radio frequency (RF) signal for plasma generation or a first bias signal, the surfaces including at least the first upper surface; and
a first insulating layer covering at least a portion of the first conductive layer, wherein
the base is formed of an insulating material.

3. The substrate support stage according to claim 2, wherein the first conductive layer is formed across the first upper surface, a first side surface between the first upper surface and the second upper surface, the second upper surface, a second side surface between the second upper surface and the lower surface, and the lower surface.

4. The substrate support stage according to claim 3, further comprising:
a second conductive layer formed on surfaces of the base and supplied with a second bias signal, the surfaces including at least the second upper surface; and
a second insulating layer covering at least a portion of the second conductive layer.

5. The substrate support stage according to claim 4, wherein the second conductive layer is formed across the second upper surface, the second side surface, and the lower surface.

6. The substrate support stage according to claim 2, wherein the second electrostatic chuck includes a bias electrode disposed in the second ceramic member and is supplied with a second bias signal.

7. The substrate support stage according to claim 1, wherein
the base is formed of a conductive material, and,
the base is supplied with at least one of an RF signal for plasma generation or a first bias signal.

8. The substrate support stage according to claim 7, wherein the base includes a first base including the lower surface of the base, and a second base including the first upper surface and the second upper surface and formed of a material different from a material of the first base.

9. The substrate support stage according to claim 8, wherein the first base and the second base are bonded to each other.

10. The substrate support stage according to claim 8, wherein the first base and the second base are fixed to each other by a fastening member.

11. The substrate support stage according to claim 8, wherein
the first base is formed of aluminum (Al) or stainless steel, and
the second base is formed of a molybdenum (Mo) alloy, a tungsten (W) alloy, or a silicon-aluminum (Si—Al) alloy.

12. The substrate support stage according to claim 7, further comprising:
a first insulating layer formed on surfaces of the base including at least the second upper surface;
a second conductive layer formed on the first insulating layer at least on the second upper surface and supplied with a second bias signal; and
a second insulating layer covering at least a portion of the second conductive layer.

13. The substrate support stage according to claim 7, wherein
the second electrostatic chuck includes a bias electrode disposed in the second ceramic member and is supplied with a second bias signal.

14. The substrate support stage according to claim 1, wherein a thickness of the first electrostatic chuck is 1 mm or less.

15. A substrate processing apparatus comprising:
the substrate support stage of claim 1.
